(19) United States
(12) Patent Application Publication
(10) Pub. No.: US 2009/0084928 A1
(43) Pub. Date: Apr. 2, 2009

(54) SUPPORT STRUCTURE FOR TERMINAL OF POINT OF SALE SYSTEM

(75) Inventor: Chien-Ta LIN, TAICHUNG CITY (TW)

Correspondence Address: BROWDY AND NEIMARK, P.L.L.C.;624 NINTH STREET, NW, SUITE 300, WASHINGTON, DC, 20001-5303, US

(73) Assignee: Universal Sciientific Industrial Co., LTD, Tsao Tuen (TW)

(21) Appl. No.: 11/969,605

(22) Filed: Jan. 4, 2008

(30) Foreign Application Priority Data
Oct. 2, 2007 (KR) 96216750

(51) Int. Cl. F16M 11/22; F16M 11/00; F16M 13/00; H05K 5/00

(52) U.S. Cl. 248/676; 248/127; 248/678

(57) ABSTRACT

A support structure for a point of sale system terminal includes a base frame having an inner back plate and two opposite inner side plates connected with two opposite sides of the inner back plate and each provided with at least one first coupling portion and at least one second coupling portion, a housing covered on the base frame and having an outer back plate and two outer side plates connected with two opposite sides of the outer base plate and each provided with at least one third coupling portion detachably coupled to the first coupling portion of the associated inner side plate of the base frame, and a shield having at least one forth coupling portion on each of two opposite sides thereof detachably coupled to the second coupling portion of one of the inner side plates of the base frame. The support structure can be assembled without tool.

### BACKGROUND OF THE INVENTION

1. Field of the Invention

The present invention relates generally to a point of sale system, and more specifically to a support structure for the terminal of a point of sale system.

2. Description of the Related Art

Point of sale (hereinafter referred to as “POS”) systems are widely in stores, supermarkets, restaurants, and hotels, as well as almost any type of retail establishment. By means of registering, computerizing and transmitting the information of the products and/or services that have been sold and/or provided through the computer-based terminals of the POS system, reliable and real-time cash, logistics and information flows can be provided for accounting, service management, customer relation management, inventory management, open to buy forecasting, and etc.

The computer-based terminal of the POS system is usually equipped with a support structure mounting on a bottom of a screen thereof for supporting the screen. In general, the support structure includes a base frame and a housing screwed to the base frame. According this design, if the support structure needs to be repaired, a maintenance worker has to use a screwdriver to remove screws one by one, thereby disassembling the housing from the base frame. After the repair of the support structure is completed, the maintenance worker must tighten the screws one by one to fasten the housing to the base frame again. It can be seen that the conventional support structure for POS system terminal has the drawback of inconvenient assembly.

### SUMMARY OF THE INVENTION

The present invention has been accomplished in view of the above-noted circumstances. It is one objective of the present invention to provide a support structure for use in a terminal of a point of sale system, which can be assembled and disassembled without any tool, thereby enhancing convenience of its assembly and repair.

To achieve this objective of the present invention, the support structure comprises a base frame, a housing and a shield. The base frame includes an inner back plate and two opposite inner side plates connected with two opposite sides of the inner back plate respectively. Each of the inner side plates is provided with at least one first coupling portion and at least one second coupling portion. The housing is covered on an outer periphery of the base frame and provided with an outer back plate corresponding to the inner back plate of the base frame, and two opposite outer side plates corresponding to the two opposite inner side plates of the base frame respectively and connected with two opposite sides of the outer back plate respectively. Each of the outer side plates has at least one third coupling portion detachably coupled to the first coupling portion of the associated inner side plate of the base frame. The shield is provided at each of two opposite sides thereof with at least one forth coupling portion detachably coupled to the second coupling portion of one of the inner side plates of the base frame.

As a result, the forth coupling portions of the shield can be easily disengaged from the second coupling portions of the base frame and the third coupling portions of the housing can be easily disengaged from the first coupling portions of the base frame, i.e. the shield and the housing can be individually and easily disassembled from the base frame without using any tool.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a perspective view of the support structure according to a preferred embodiment of the present invention;

FIG. 2 is a perspective view of the base frame and the base of the support structure according to the preferred embodiment of the present invention;

FIG. 3 is a perspective view of the housing of the support structure according to the preferred embodiment of the present invention; FIG. 4 is a perspective view of the shield of the support structure according to the preferred embodiment of the present invention;

FIG. 5 is a front view of the support structure according to the preferred embodiment of the present invention, in which the shield is removed for illustrative purpose;

FIG. 6 is a left side and partially cutaway view of the support structure according to the preferred embodiment of the present invention, and

FIG. 7 is a front and partially cutaway view of the support structure according to the preferred embodiment of the present invention.

### DETAILED DESCRIPTION OF THE INVENTION

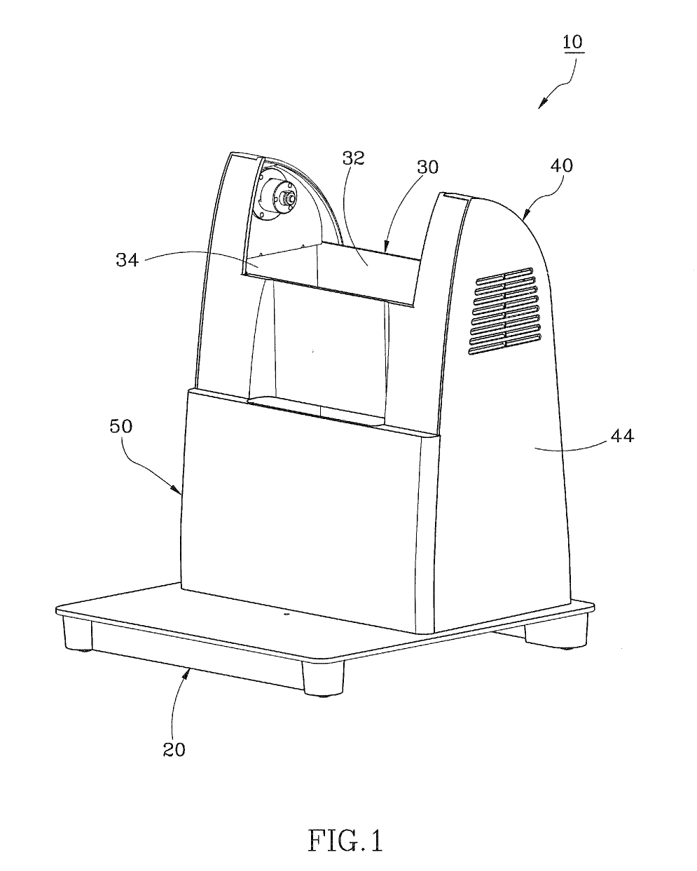

Referring to FIG. 1, a support structure 10 for a POS system terminal in accordance with a preferred embodiment of the present invention comprises a base 20, a base frame 30, a housing 40 and a shield 50.

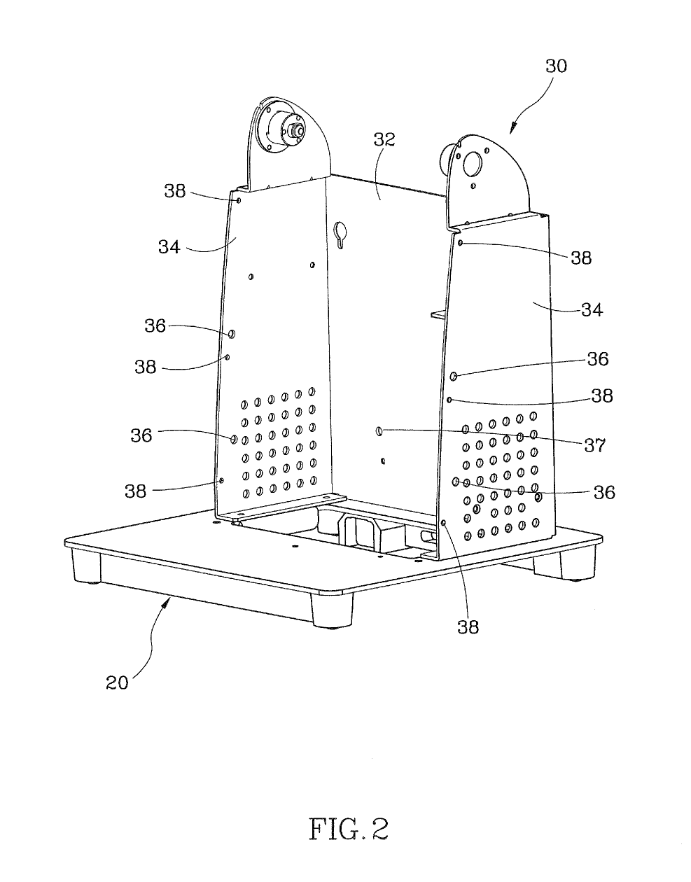

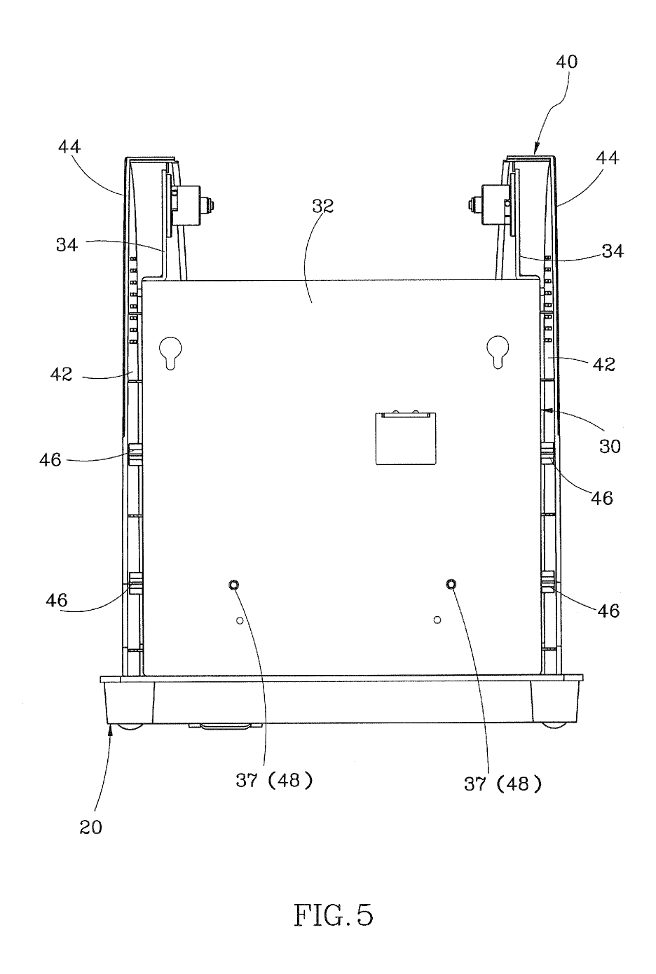

The base frame 30 can be made of, but not limited to, metal materials. As shown in FIGS. 2 and 5, the base frame 30 includes an inner back plate 32 mounted on the base 20 and provided with two fifth coupling portions 37, and two inner side plates 34 mounted on the base 20 respectively and each having one side orthogonally connected with one of the two opposite sides of the inner back plate 32 such that the two inner side plates 34 face with each other. The two inner side plates 34 each have two first coupling portions 36 and three second coupling portions 38. The first coupling portions 36 of one of the inner side plates 34 are aligned with the first coupling portions 36 of the other inner side plate 34, and the second coupling portions 38 of one of the inner side plates 34 are aligned with the second coupling portions 38 of the other inner side plate 34. In this embodiment, the fifth coupling portions 37 of the inner back plate 32 and the first coupling portions 36 of the inner side plates 34 are embodied as first holes, and the second coupling portions 38 of the inner side plates 34 are embodied as second holes, which have a diameter smaller than that of the first holes.

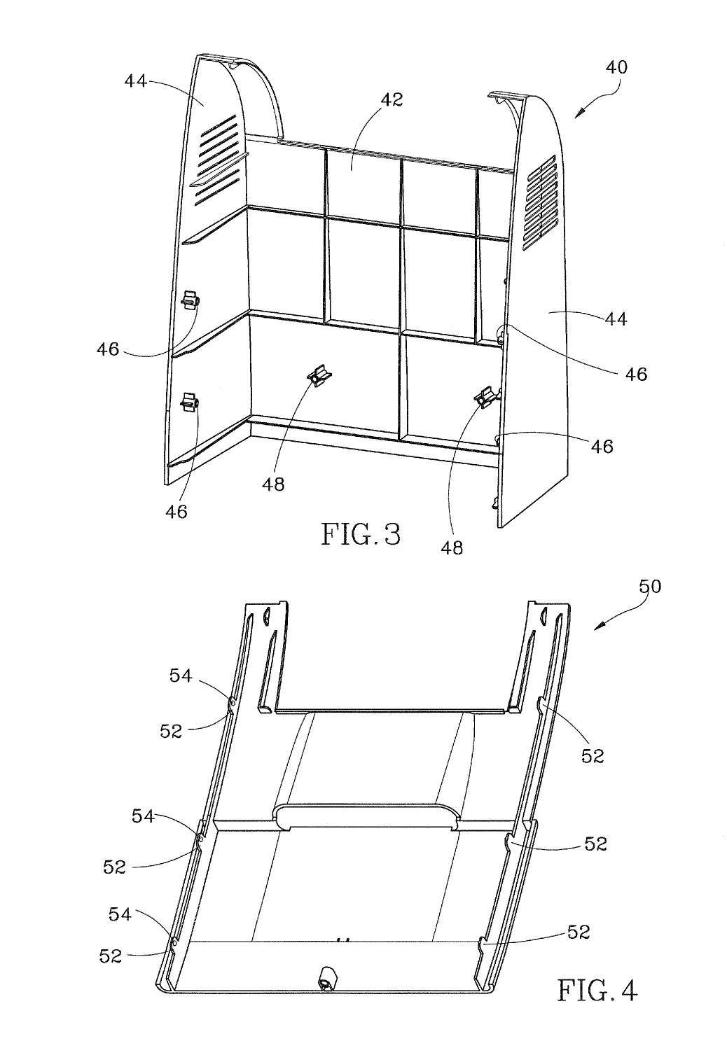

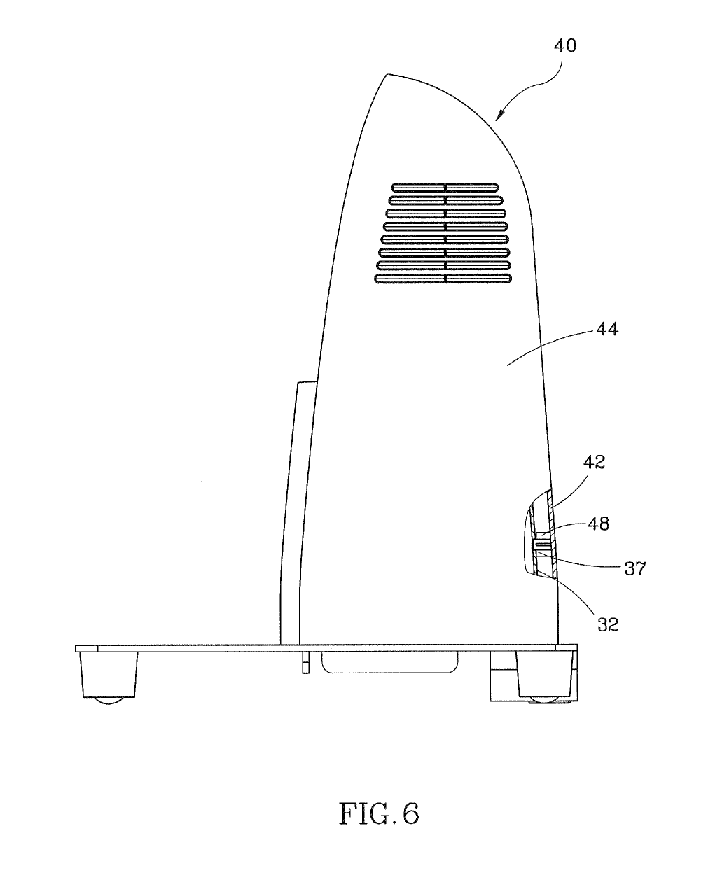

The housing 40 can be made of, but not limited to, plastics. As shown in FIG. 3, the housing 40 includes an outer back plate 42 having two sixth coupling portions 48 corresponding to the fifth coupling portions 37 of the inner back plate 32 of the base frame 30, and two outer side plates 44 orthogonally connected with two opposite sides of the outer back plate 42 such that the outer back plate 42 and the outer side plates 44 are respectively corresponding to the inner back plate 32 and the inner side plates 34 of the base frame 30. The outer side plates 44 each have two third coupling portions 46 corresponding to the first coupling portions 36 of one of the inner side plates 34 of the base frame 30. In this embodiment, the sixth coupling portions 48 and the third coupling portions 46 are embodied as positioning pins each having a free end insertable into one of the first holes, i.e. the first coupling portions 36 and the fifth coupling portions 37 of the base frame 30, for fastening the housing 40 to the base frame 30, as shown in FIGS. 5 and 6.

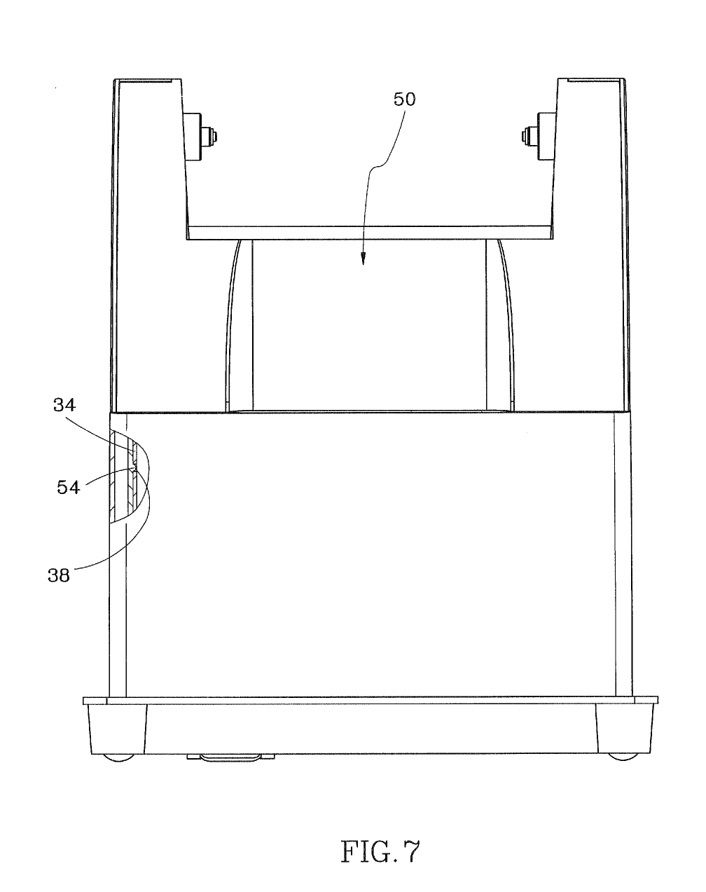

The shield 40 can be made of, but not limited to, plastics. As shown in FIG. 4, the shield 40 has three lugs 52 on each of the two opposite sides thereof, and a forth coupling portion 54 provided on the inner surface of each of the lugs 52. In this embodiment, the forth coupling portions 54 are embodied as protrusions insertable into the second holes, i.e. the second coupling portions 38 of the base frame 30, for fastening the shield 50 to the base frame 30 and enabling left and right sides of the shield 50 to be contacted with the outer side plates 44 of the housing 40, as shown in FIG.7.

In assembly of the support structure 10 of the present invention, because the housing 40 is made of plastics having a certain flexibility, the outer side plates 44 of the housing 40 can be pulled outwardly for enabling the housing 40 to cover on the outer periphery of the base frame 30 in such a way that the positioning pins, i.e. the sixth coupling portions 48 of the outer back plate 42 of the housing 40 and the third coupling portions 46 of the outer side plate 44 of the housing 40, can be inserted into the first holes, i.e. the fifth coupling portions 37 of the inner back plate 32 of the base frame 30 and the first coupling portions 36 of the inner side plate 34 of the base frame 30, thereby fixing the housing 40 to the base frame 30, as shown in FIGS. 5 and 6. Thereafter, the user can aim the lugs 52 of the shield 50 at the second coupling portions 38 of the inner side plates 34 of the base frame 30 and push the shield 50 forward in such a way that the protrusions, i.e. the forth coupling portions 54 of the shield 50 can be inserted into the second holes, i.e. the second coupling portions 38 of the inner side plates 34 of the base frame 30, as shown in FIG. 7, causing the left and right sides of the shield 50 to be contacted with the outer side plates 44 of the housing 40. As a result, the assembly of the support structure 10 is completed.

On the contrary, when the user would like to disassemble the support structure 10, he/she can pull the two sides of the shield 50 outwardly to forcedly disengage the protrusions, i.e. the forth coupling portions 54 of the shield 50, from the second holes, i.e. the second coupling portions 38 of the inner side plate 34 of the base frame 30, and then remove the shield 50 from the base frame 30. Thereafter, pull the outer side plates 44 of the housing 40 outwardly to disengage the positioning pins, i.e. the third coupling portions 46 of the outer side plates 44 of the housing 40, from the first holes, i.e. the first coupling portions 36 of the inner side plates 34 of the base frame 30, and then pull the outer back plate 42 of the housing 40 away from the inner back plate 32 of the base frame 30 so as to disengage the sixth coupling portions 48 (i.e., the positioning pins) of the outer back plate 42 of the housing 40 from the fifth coupling portions 37 (i.e., the first holes) of the inner back plate 32 of the base frame 30 to remove the housing 40 from the base frame 30.

It is to be easily understood that the support structure can be made with various kinds of design on the basis of the spirit of the present invention. For example, the number of the first coupling portions and the second coupling portions of the base frame are not limited to the above-mentioned embodiment as long as the first coupling portions of the inner side plates of the base frame can be matched with the third coupling portions of the housing and the second coupling portions of the inner side plates of the base frame can be matched with the forth coupling portions of the shield.

In conclusion, the support structure of the invention can be assembled and disassembled without using any tool, thereby enhancing convenience of assembly and repair.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A support structure for a point of sale system terminal, the support structure comprising:
a base frame having an inner back plate, and two opposite inner side plates connected with two opposite sides of the inner back plate respectively, wherein each of the inner side plates has at least one first coupling portion and at least one second coupling portion;
a housing covered on an outer periphery of the base frame and having an outer back plate corresponding to the inner back plate of the base frame, and two opposite outer side plates corresponding to the two opposite inner side plates of the base frame respectively and connected with two opposite sides of the outer back plate respectively, wherein each of the outer side plates has at least one third coupling portion detachably coupled to the first coupling portion of the associated inner side plate of the base frame; and
a shield corresponding to the inner back plate of the base frame and provided at each of two opposite sides thereof with at least one forth coupling portion detachably coupled to the second coupling portion of one of the two opposite inner side plates of the base frame.

2. The support structure as claimed in claim 1, wherein each said first coupling portion of the inner side plates of the base frame is a hole and each said third coupling portion of the outer side plates of the housing is a pin inserted into the hole.

3. The support structure as claimed in claim 1, wherein each said second coupling portion of the inner side plates of the base frame is a hole and each said fourth coupling portion of the shield is a protrusion which protrudes from a lug provided at one of the two sides of the shield and is inserted into the hole.

4. The support structure as claimed in claim 1 wherein the inner back plate of the base frame further includes at least one fifth coupling portion and the outer back plate of the housing farther includes at least one sixth coupling portion detachably coupling to the at least one fifth coupling portion of the inner back plate of the base frame.

5. The support structure as claimed in claim 4, wherein the fifth coupling portion of the inner back plate of the base frame is a hole and the sixth coupling portion of the outer back plate of the housing is a pin inserted into the hole.

6. The support structure as claimed in claim 5, wherein the inner back plate of the base frame has two said fifth coupling portions and the outer back plate of the housing has two said sixth coupling portions.

7. The support structure as claimed in claim 1, wherein the inner side plates of the base frame each have two said first coupling portions and the outer side plates of the housing each have two said third coupling portions.

8. The support structure as claimed in claim 1, wherein the inner side plates of the base frame each have three said second coupling portions and the outer side plates of the housing each have three said forth coupling portions.

9. The support structure as claimed in claim 1, further comprising a base mounted with a bottom of the base frame.
